(19) United States
(12) Patent Application Publication
(10) Pub. No.: US 2025/0140568 A1
(43) Pub. Date: May 1, 2025

(54) METHODS OF MANUFACTURING SEMICONDUCTOR DEVICES

(71) Applicant: SAMSUNG ELECTRONICS CO., LTD., Suwon-si (KR)

(72) Inventors: SangHyuk YOO, Suwon-si (KR); Songyun KANG, Suwon-si (KR); Jiwon SON, Suwon-si (KR)

(21) Appl. No.: 18/640,322

(22) Filed: Apr. 19, 2024

(30) Foreign Application Priority Data
Oct. 27, 2023 (KR) 10-2023-0146047

(51) Int. Cl. H01L 21/3115; H01L 21/02; H01L 21/311

(52) U.S. Cl. CPC H01L 21/31155; H01L 21/02164; H01L 21/0234; H01L 21/31116; H01L 21/31144

(57) ABSTRACT

The present disclosure relates to methods of manufacturing semiconductor devices, and a method for manufacturing a semiconductor device according to an embodiment comprises: forming an insulating layer including a silicon compound on a substrate; forming a trench by recessing a portion of the insulating layer toward the substrate, wherein the trench is adjacent a first portion of the insulating layer and a second portion of the insulating layer; implanting a first impurity with a first concentration in the first portion of the insulating layer; implanting a second impurity with a second concentration in the second portion of the insulating layer, wherein the implanting the first impurity and the implanting the second impurity are performed simultaneously; and etching the first portion of the insulating layer after the implanting the first impurity, wherein the first impurity and the second impurity each include at least one of boron and arsenic.

### CROSS-REFERENCE TO RELATED APPLICATIONS

This application claims priority to and the benefit of Korean Patent Application No. 10-2023-0146047 filed at the Korean Intellectual Property Office on Oct. 27, 2023, the entire contents of which are incorporated herein by reference.

### BACKGROUND OF THE INVENTION

The present disclosure relates to a semiconductor device and a method for manufacturing (fabricating) the same.

Deposition processes, ion implantation processes, photolithography processes, an etching process, and the like are used to implement unit elements with a fine critical dimension (CD) when an integrated circuit element with a reduced design rule is formed as down-scaling and high integration of the integrated circuit element have recently progressed rapidly.

For example, multiple unit processes using a plasma device may be used to form the unit elements with the fine critical dimension (CD) or a structure with a high aspect ratio.

### SUMMARY OF THE INVENTION

Embodiments are to provide semiconductor devices with improved reliability and productivity and methods for manufacturing the semiconductor devices.

A method for manufacturing a semiconductor device according to an embodiment comprises: forming an insulating layer including a silicon compound on a substrate; forming a trench by recessing a portion of the insulating layer toward the substrate, wherein the trench is adjacent a first portion of the insulating layer and a second portion of the insulating layer; implanting a first impurity with a first concentration in the first portion of the insulating layer; implanting a second impurity with a second concentration in the second portion of the insulating layer, wherein the implanting the first impurity and the implanting the second impurity are performed simultaneously; and etching the first portion of the insulating layer after the implanting the first impurity, wherein the first impurity and the second impurity each include at least one of boron and arsenic.

A method for manufacturing a semiconductor device according to an embodiment comprises: forming an insulating layer including a silicon compound on a substrate; forming a mask pattern on the insulating layer; forming a trench in the insulating layer by patterning the insulating layer through the mask pattern, wherein an upper surface of a first portion of the insulating layer and an inner side surface of a second portion of the insulating layer are exposed to the trench; implanting a first impurity into the first portion of the insulating layer by using a first plasma gas; and etching the first portion of the insulating layer by using a second plasma gas, wherein the first impurity includes at least one of boron and arsenic.

A method for manufacturing a semiconductor device according to an embodiment comprises: forming an insulating layer that includes a silicon compound on a substrate; forming a mask pattern on the insulating layer; forming a trench in the insulating layer by patterning the insulating layer through the mask pattern; forming a sacrificial layer on the mask pattern and an inner side surface of the insulating layer, which is exposed to the trench, by using a first plasma gas; implanting an impurity into an upper surface of the insulating layer, which is exposed to the trench, by using a second plasma gas; and etching the upper surface of the insulating layer by using a third plasma gas, wherein a unit cycle, in which the forming the sacrificial layer, the implanting the impurity, and the etching the upper surface of the insulating layer is sequentially performed, is repeated more than once, and wherein the first plasma gas, the second plasma gas, and the third plasma gas include boron.

According to the embodiments, a semiconductor device with improved reliability and productivity and a method for manufacturing the semiconductor device using a plurality of unit processes including deposition processes, ion implantation processes, and an etching process using a plasma device, may be provided.

### BRIEF DESCRIPTION OF THE DRAWINGS

FIG. 1 is a cross-sectional view showing a portion of a semiconductor device according to some embodiments.

FIG. 2 is a partially enlarged view of a region R1 of FIG. 1.

FIG. 3, FIG. 4, FIG. 6, and FIG. 7 are cross-sectional views for describing a method for manufacturing the semiconductor device according to some embodiments.

FIG. 5 is a timing diagram showing a cycle of a process for etching a portion of an insulating layer according to some embodiments.

FIG. 8 is a view showing a chemical structure before an impurity is implanted into the insulating layer including silicon oxide.

FIG. 9 is a view showing a chemical structure after an impurity is implanted into the insulating layer including silicon oxide.

FIG. 10, FIG. 12, and FIG. 13 are timing diagrams showing a cycle of a process of etching a portion of the insulating layer according to some embodiments.

FIG. 11 and FIG. 14 are cross-sectional views for describing a method for manufacturing the semiconductor device according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the scope of the present disclosure.

In order to clearly describe the present disclosure, parts or portions that are irrelevant to the description may be omitted, and identical or similar constituent elements throughout the specification may be denoted by the same reference numerals unless clearly stated otherwise.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

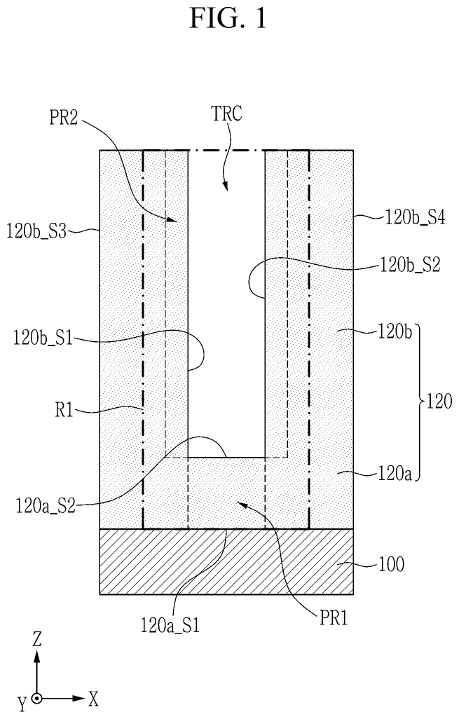

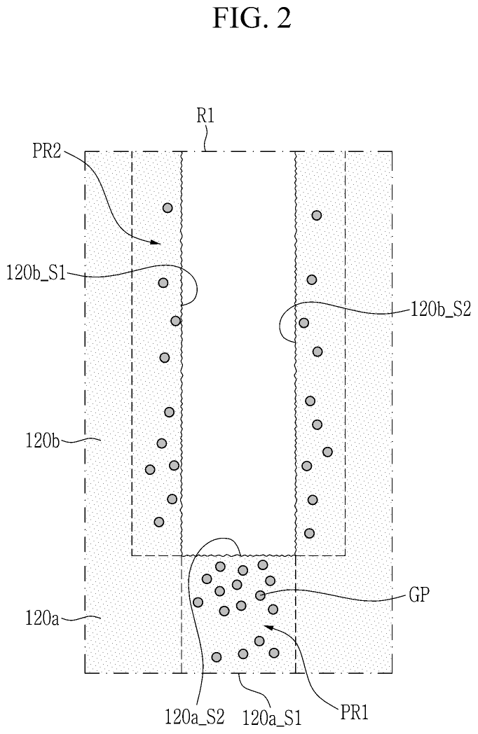

FIG. 1 is a cross-sectional view showing a portion of a semiconductor device according to some embodiments. FIG. 2 is a partially enlarged view of a region R1 of FIG. 1.

Referring to FIG. 1 and FIG. 2, the semiconductor device according to the embodiment may include a substrate 100 and an insulating layer 120 disposed on the substrate 100. In order to mainly describe the insulating layer 120 disposed on the substrate 100, illustration of other components may be omitted in FIG. 1.

The substrate 100 may have an upper surface parallel to a first direction X and a second direction Y, and may have a thickness in a third direction Z perpendicular to the first direction X and the second direction Y.

The substrate 100 may be a semiconductor substrate including a semiconductor material. For example, the substrate 100 may be the semiconductor substrate made of the semiconductor material, or may be the semiconductor substrate with a semiconductor layer formed on a base substrate. The substrate 100 may include, for example, silicon, epitaxial silicon, germanium, silicon-germanium, silicon on insulator (SOI), germanium on insulator (GOI), and/or the like. As used herein, the term “and/or” includes any and all combinations of one or more of the associated listed items. Expressions such as “at least one of,” when preceding a list of elements, modify the entire list of elements and do not modify the individual elements of the list.

The semiconductor material included in the substrate 100 may be doped with a P-type impurity and/or a N-type impurity. For example, the semiconductor material included in the substrate 100 may be doped with the N-type impurity (e.g., phosphorus (P), arsenic (As), and/or the like). However, a conductivity type, a material, or the like of the impurity doped in the semiconductor material is not limited thereto, and may be variously changed.

The insulating layer 120 may be disposed on the substrate 100. The insulating layer 120 may include a first portion 120a extending in the first direction X that is a direction parallel to the substrate 100 (e.g., the upper surface of the substrate 100), and second portions 120b extending from the first portion 120a in the third direction Z that is a direction perpendicular to the substrate 100 (e.g., the upper surface of the substrate 100). The second portions 120b may be spaced apart from each other in the first direction X.

The first portion 120a of the insulating layer 120 may include a first surface (e.g., a lower surface) 120a_S1 in contact with the upper surface of the substrate 100 and a second surface (e.g., an upper surface) 120a_S2 that is opposite to the first surface 120a_S1. That is, the first surface 120a_S1 and the second surface 120a_S2 may face each other in the third direction Z.

The second portions 120b of the insulating layer 120 may include a first side surface (e.g., an inner side surface) 120b_S1 and a second side surface (e.g., another inner side surface) 120b_S2 facing each other while being spaced apart from each other in the first direction X with the second surface 120a_S2 of the first portion 120a interposed therebetween. The second portions 120b of the insulating layer 120 may include a third side surface (e.g., an outer side surface) 120b_S3 opposite to the first side surface 120b_S1, and a fourth side surface (e.g., another outer side surface) 120b_S4 opposite to the second side surface 120b_S2. That is, the first side surface 120b_S1 and the third side surface 120b_S3 may face each other in the first direction X, and the second side surface 120b_S2 and the fourth side surface 120b_S4 may face each other in the first direction X.

The insulating layer 120 may include a trench TRC. That is, the trench TRC may be recessed from an upper (e.g., an uppermost) surface of the insulating layer 120 toward a lower surface thereof.

The trench TRC may be defined by the first portion 120a and the second portions 120b of the insulating layer 120. For example, the trench TRC may be a space surrounded by the first portion 120a and the second portions 120b of the insulating layer 120. That is, the trench TRC may be defined (e.g., may be surrounded) by the second surface 120a_S2 of the first portion 120a, the first side surface 120b_S1 of the second portion 120b, and the second side surface 120b_S2 of the second portion 120b. For example, the second surface 120a_S2 of the first portion 120a, the first side surface 120b_S1 of the second portion 120b, and the second side surface 120b_S2 of the second portion 120b may be exposed to the trench TRC. The second surface 120a_S2 of the first portion 120a may form a lower surface of the trench TRC, and each of the first side surface 120b_S1 and the second side surface 120b_S2 of the second portion 120b may form a side surface of the trench TRC.

In FIG. 1 and FIG. 2, each of the lower surface and the side surface of the trench TRC of the insulating layer 120 may include (e.g., may be) a straight line and the trench TRC may have (e.g., may be) a quadrangular shape in a cross-section, but a shape of the trench TRC is not limited thereto, and may be variously changed. For example, each of the lower surface and the side surface of the trench TRC of the insulating layer 120 may include (e.g., may be) a curved line. The trench TRC may be concave toward the substrate 100 in a cross-section. For example, the insulating layer 120 may include a portion (e.g., the trench TRC) that is recessed toward the substrate 100 in a cross-section. That is, each of the second surface 120a_S2 of the first portion 120a constituting the lower surface of the trench TRC and the first side surface 120b_S1 and the second side surface 120b_S2 of the second portion 120b constituting the side surface of the trench TRC may include (e.g., may be) a curved line. The second surface 120a_S2 of the first portion 120a constituting the lower surface of the trench TRC may be connected as a curved line to each of the first side surface 120b_S1 and the second side surface 120b_S2 of the second portion 120b constituting the side surface of the trench TRC.

The insulating layer 120 may include a silicon compound. For example, the insulating layer 120 may include, for example, silicon oxide, silicon nitride, silicon oxynitride, a low-k material (a low dielectric constant material) such as SiOCN, SiOC, SiBN, SiBCN, or SiBCON, and/or a combination thereof. However, a material included in the insulating layer 120 is an example and is not limited thereto, and may be variously changed.

In an embodiment, the insulating layer 120 may include a plasma-treated region, such as a first plasma region PR1 and a second plasma region PR2. The first plasma region PR1 and the second plasma region PR2 may be adjacent the trench TRC. That is, the first portion 120a of the insulating layer 120 disposed between the second portions 120b and constituting the bottom surface of the trench TRC may include the first plasma region PR1, and the second portions 120b facing each other in the first direction X and constituting the side surfaces of the trench TRC may include the second plasma region PR2. The first plasma region PR1 may mean a region (e.g., a portion of the first portion 120a) disposed between the first surface 120a_S1 and the second surface 120a_S2 (in the third direction Z) and disposed between the second portions 120b of the insulating layer 120 (in the first direction X).

The second plasma region PR2 may refer to a region (e.g., a portion of the second portions 120b) disposed between the first side surface 120b_S1 and the third side surface 120b_S3 (in the first direction X) and between the second side surface 120b_S2 and the fourth side surface 120b_S4 (in the first direction X).

Specifically, the second plasma region PR2 may mean a region (e.g., a portion of the second portions 120b) disposed closer to the first side surface 120b_S1 than to the third side surface 120b_S3 between the first side surface 120b_S1 and the third side surface 120b_S3, and a region (e.g., a portion of the second portions 120b) disposed closer to the second side surface 120b_S2 than to the fourth side surface 120b_S4 between the second side surface 120b_S2 and the fourth side surface 120b_S4. That is, the second plasma region PR2 included in each of the second portions 120b may face each other in the first direction X to be disposed adjacent to the side surface of the trench TRC.

In an embodiment, a depth of the first plasma region PR1 and a depth of the second plasma region PR2 may be different. For example, the depth of the first plasma region PR1 may be greater than the depth of the second plasma region PR2. Here, the depth of the first plasma region PR1 may mean a depth along the third direction Z, and the depth of the second plasma region PR2 may mean a depth along the first direction X. This may be due to a difference in depths at which impurities GP included in a plasma gas are implanted in a step S220 of implanting the impurity GP into the insulating layer 120 using plasma to be described later with reference to FIG. 6. A detailed description of this is provided later. However, a relationship (e.g., the difference) between the depth of the first plasma region PR1 and the depth of the second plasma region PR2 is not limited thereto, and may be variously changed.

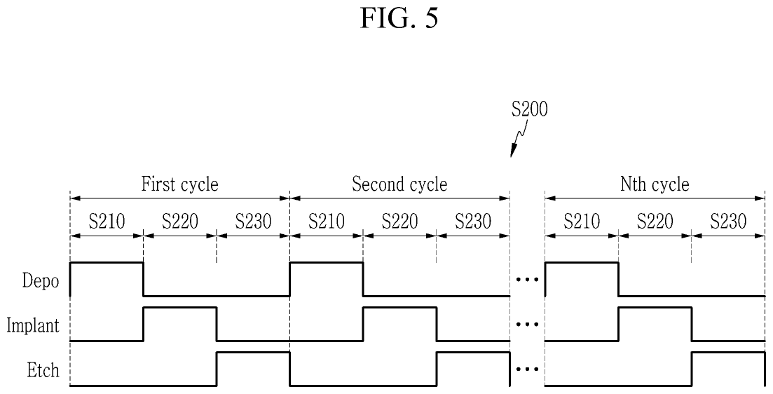

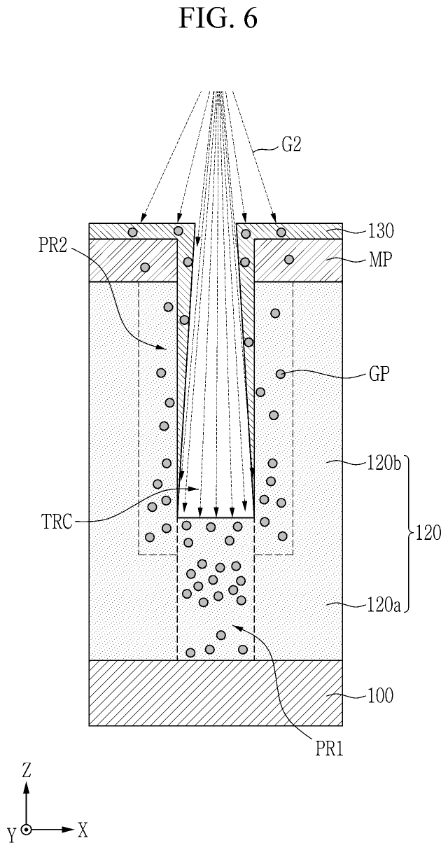

In an embodiment, the first plasma region PR1 and the second plasma region PR2 of the insulating layer 120 may include the impurity GP. Here, the impurity GP may be a material included in the plasma gas that will be described later with reference to FIG. 6. For example, the impurity GP may include boron (B), arsenic (As), and/or phosphorus (P). However, materials included in the first plasma region PR1 and the second plasma region PR2 of the insulating layer 120 (e.g., the impurity GP) are not limited thereto, and may be variously changed. That is, in the step S220 of FIG. 5 of implanting the impurity GP into the insulating layer 120 using the plasma to be described later, the materials (e.g., the impurity GP) included in the first plasma region PR1 and the second plasma region PR2 may be variously changed according to materials included in the plasma gas.

In an embodiment, a concentration of the impurity GP included in the first plasma region PR1 of the insulating layer 120 and a concentration of the material included in the second plasma region PR2 may be different. For example, the concentration of the impurity GP included in the first plasma region PR1 may be higher than the concentration of the impurity GP included in the second plasma region PR2. A density of the number of the impurities GP included in the first plasma region PR1 may be greater than a density of the number of the impurities GP included in the second plasma region PR2. The number of particles of the impurity GP per unit volume included in the first plasma region PR1 may be greater than the number of particles of the impurity GP per unit volume included in the second plasma region PR2.

The concentration of the impurity GP included in the first plasma region PR1 may gradually (and generally) decrease along a direction in which the impurity GP is implanted from the second surface 120a_S2 of the first portion 120a of the insulating layer 120 constituting the lower surface of the trench TRC. For example, (in general) a portion of the first plasma region PR1 closer to the substrate 100 may have a lower concentration of the impurity GP. As the first plasma region PR1 gets closer to the substrate 100, the concentration of the impurity GP within the first plasma region PR1 may (generally) decrease. The concentration of the impurity GP included in the first plasma region PR1 may (generally) decrease as the first plasma region PR1 approaches the substrate 100. The concentration of the impurity GP included in the first plasma region PR1 may (generally) decrease as the first plasma region PR1 moves from the second surface 120a_S2 of the first portion 120a to the first surface 120a_S1.

Accordingly, the first plasma region PR1 may have a concentration gradient with respect to the impurity GP. However, the concentration gradient of the impurity GP included in the first plasma region PR1 is not limited thereto, and in an etching step to be described later with reference to FIG. 7, the concentration gradient of the impurity GP included in the first plasma region PR1 may be variously changed according to a thickness of the first plasma region PR1 to be etched. For example, in some embodiments, the concentration of the impurity GP included in the first plasma region PR1 may have a concentration gradient that increases and then decreases as the first plasma region PR1 approaches (gets closer to) the substrate 100.

This may be due to a difference in depths at which the impurities GP are implanted into in the first plasma region PR1 in the step S220 of implanting the impurity GP into the insulating layer 120 using the plasma to be described later with reference to FIG. 6.

A concentration of the impurity GP included in an upper region of the second plasma region PR2 may be different from a concentration of the impurity GP included in a lower region of the second plasma region PR2. The concentration of the impurity GP included in the second plasma region PR2 may (generally) increase from the upper region of the second plasma region PR2 to the lower region of the second plasma region PR2. A concentration of the impurity GP included in the lower region of the second plasma region PR2 that is disposed adjacent (closer) to the first plasma region PR1 may be (generally) higher than a concentration of the impurity GP included in the upper region of the second plasma region PR2 that is disposed far (farther) from the first plasma region PR1. As the second plasma region PR2 gets closer to the substrate 100, the concentration of the impurity GP within the second plasma region PR2 may (generally) increase. Accordingly, the second plasma region PR2 may have a concentration gradient with respect to the impurity GP. Herein the terms “lower”, “higher”, “lower level”, “higher level”, and the like may refer to a relative distance from the upper/lower surface of the substrate 100 in the third direction Z. For example, when an element A is described as lower than an element B, the element A may be closer than the element B to the upper/lower surface of the substrate 100 in the third direction Z.

In an embodiment, the concentration gradient for the impurity GP of the first plasma region PR1 may be different from the concentration gradient for the impurity GP of the second plasma region PR2. The degree of variation of the concentration of the impurity GP in the first plasma region PR1 may be different from the degree of variation of the concentration of the impurity GP in the second plasma region PR2. For example, the degree of variation of the concentration of the impurity GP in the first plasma region PR1 may be greater than the degree of variation of the concentration of the impurity GP in the second plasma region PR2. However, the present disclosure is not limited thereto, and a relationship (e.g., a difference) between the concentration gradient of the impurity GP in the first plasma region PR1 and the concentration gradient of the impurity GP in the second plasma region PR2 may be variously changed.

As described above, a difference in concentration between the impurities GP included in the first plasma region PR1 and the second plasma region PR2 and a difference in concentration between the impurities GP included in the upper and lower regions of the second plasma region PR2 may be due to a difference in angles at which the material (e.g., the impurities GP) included in the plasma gas is implanted into the first plasma region PR1 and the second plasma region PR2 in the step S220 of implanting the impurity GP into the insulating layer 120 using the plasma to be described later with reference to FIG. 6. Here, the angle at which the impurities GP are implanted may refer to an angle with respect to the upper surface of the substrate 100.

That is, in the plasma treatment step, the impurities GP implanted into the first plasma region PR1 and the second plasma region PR2 may be implanted at a specific angle range. The impurities GP implanted in the first plasma region PR1 may be implanted at a narrow (a narrower) angle (angle range), the impurities GP implanted in the second plasma region PR2 may be implanted at a relatively wide (a wider) angle (angle range) compared with the impurities GP implanted in the first plasma region PR1, and the number of the impurities GP implanted at the narrow (the narrower) angle (angle range) may be greater than the number of the impurities GP implanted at the wide (the wider) angle (angle range). The impurities GP implanted in the first plasma region PR1 may be implanted with relatively high (higher) straightness compared with the impurities GP implanted in the second plasma region PR2.

As the number of the impurities GP implanted in the first plasma region PR1 increases than the number of the impurities GP implanted in the second plasma region PR2, the concentration of the impurity GP included in the first plasma region PR1 may be higher than the concentration of the impurity GP included in the second plasma region PR2.

As the impurities GP implanted into the second plasma region PR2 are implanted at a relatively wide (wider) angle (angle range) compared with the impurities GP implanted into the first plasma region PR1 so that straightness is lowered, the impurities GP implanted into the second plasma region PR2 may be implanted to have a relatively wide (wider) distribution compared with the impurities GP implanted into the first plasma region PR1. Because the impurities GP implanted into the lower region of the second plasma region PR2 are implanted at a relatively narrow (narrower) angle compared with the impurities GP implanted into the upper region of the second plasma region PR2, the number of the impurities GP implanted into the lower region of the second plasma region PR2 may be greater than the number of the impurities GP implanted into the upper region of the second plasma region PR2.

Accordingly, the concentration of the impurity GP included in the lower region of the second plasma region PR2 may be higher than the concentration of the impurity GP included in the upper region of the second plasma region PR2.

In an embodiment, a curved (e.g., an uneven, a bumpy, a wavy, an embossed, or the like) portion may be formed at the second surface 120a_S2 of the first portion 120a of the insulating layer 120 where the first plasma region PR1 is disposed in the step S220 of implanting the impurity GP into the insulating layer 120 using the plasma to be described later with reference to FIG. 6 and a step S230 of etching a portion of the insulating layer 120 using the plasma, and a curved portion may be formed at the first side surface 120b_S1 of the second portion 120b where second plasma region PR2 is disposed in the step S220 of implanting the impurity GP into the insulating layer 120 using the plasma to be described later with reference to FIG. 6. For example, the second surface 120a_S2 of the first portion 120a and the first side surface 120b_S1 of the second portion 120b may be uneven (e.g., bumpy, wavy, embossed, or the like) surfaces. Accordingly, the second surface 120a_S2 of the first portion 120a of the insulating layer 120 and the first side surface 120b_S1 of the second portion 120b may have a surface roughness. Herein, roughness (or degree of roughness) may refer to the degree or the frequency of curved (e.g., the uneven, the bumpy, the wavy, the embossed, or the like) portions formed on a surface. For example, the roughness (or degree of roughness) may be measured by an average of profile height deviations from the mean line of the surface.

In an embodiment, the second surface 120a_S2 of the first portion 120a and the first side surface 120b_S1 of the second portion 120b of the insulating layer 120 may have different surface roughnesses (different degrees of surface roughness). For example, the (degree of) surface roughness of the second surface 120a_S2 of the first portion 120a may be greater than the (degree of) surface roughness of the first side surface 120b_S1 of the second portion 120b. That is, the first side surface 120b_S1 of the second portion 120b may have a relatively smooth (smoother) surface compared with the second surface 120a_S2 of the first portion 120a.

The surface roughness of the second surface 120a_S2 of the first portion 120a of the insulating layer 120 and the surface roughness of the first side surface 120b_S1 of the second portion 120b of the insulating layer 120 have been mainly described. Because the first side surface 120b_S1 and the second side surface 120b_S2 of the second portion 120b of the insulating layer 120 are symmetrically disposed, the contents of a relationship between the surface roughness of the second surface 120a_S2 of the first portion 120a and the surface roughness of the first side surface 120b_S1 of the second portion 120bmay be substantially equally applied to a relationship between the surface roughness of the second surface 120a_S2 of the first portion 120a and a surface roughness of the second side surface 120b_S2 of the second portion 120b. For example, the second side surface 120b_S2 of the second portion 120b may have a relatively smooth (smoother) surface compared with the second surface 120a_S2 of the first portion 120a.

As described above, in the step S220 of implanting the impurity GP into the insulating layer 120 using the plasma to be described later with reference to FIG. 6, the number of the impurities GP implanted in the first plasma region PR1 may be relatively greater than the number of the impurities GP implanted in the second plasma region PR2. Thus, a degree or a frequency of the curved (e.g., the uneven, the bumpy, the wavy, the embossed, or the like) portion formed (occurring) on the second surface 120a_S2 of the first portion 120a of the insulating layer 120 may be relatively greater than a degree or a frequency of the curved (e.g., the uneven, the bumpy, the wavy, the embossed, or the like) portion formed (occurring) on the first side surface 120b_S1 of the second portion 120b.

As the step S230 of etching the portion of the insulating layer 120 using the plasma is additionally performed after the step S220 of implanting the impurity GP into the insulating layer 120 using the plasma is performed, the number of times the first plasma region PR1 is exposed to the plasma may be relatively greater than the number of times the second plasma region PR2 is exposed to the plasma.

Accordingly, (the surface roughness of) the second surface 120a_S2 of the first portion 120a may be rougher than (the surface roughness of) the first side surface 120b_S1 of the second portion 120b. However, the relationship (e.g., the difference) between the surface roughness of the second surface 120a_S2 of the first portion 120a and the surface roughness of the first side surface 120b_S1 of the second portion 120b is not limited thereto, and may be variously changed.

For example, as the step S220 of implanting the impurity GP into the insulating layer 120 using the plasma to be described later with reference to FIG. 6 is performed, the degree or the frequency of the curved (e.g., the uneven, the bumpy, the wavy, the embossed, or the like) portion formed on the second surface 120a_S2 of the first portion 120a of the insulating layer 120 may be greater than the degree or the frequency of the curved (e.g., the uneven, the bumpy, the wavy, the embossed, or the like) portion formed on the first side surface 120b_S1 of the second portion 120b. Thus, the surface roughness of the second surface 120a_S2 of the first portion 120a of the insulating layer 120 may be greater than the surface roughness of the first side surface 120b_S1 of the second portion 120b of the insulating layer 120.

Thereafter, in the step S230 of etching the portion of the insulating layer 120 using the plasma, a portion of a surface of the first portion 120a of the insulating layer 120 may be etched, and the curved (e.g., the uneven, the bumpy, the wavy, the embossed, or the like) portion formed on the second surface 120a_S2 of the first portion 120a may be etched together. On the other hand, as the curved portion (e.g., the uneven, the bumpy, the wavy, the embossed, or the like) formed on the first side surface 120b_S1 of the second portion 120b is maintained as is, the surface roughness of the first side surface 120b_S1 of the second portion 120b of the insulating layer 120 may be greater than the surface roughness of the second surface 120a_S2 of the first portion 120a. The second surface 120a_S2 of the first portion 120a of the insulating layer 120 may have a relatively smooth surface (may be smoother) compared with the first side surface 120b_S1 of the second portion 120b.

In an embodiment, electrical resistivity of the first plasma region PR1 of the insulating layer 120 may be different from electrical resistivity of the second plasma region PR2 of the insulating layer 120. For example, the electrical resistivity of the first plasma region PR1 may be lower (less) than that of the second plasma region PR2.

As described above, this may be due to a difference between the number of the impurities GP implanted into the first plasma region PR1 of the insulating layer 120 and the number of the impurities GP implanted into the second plasma region PR2 of the insulating layer 120 in the step S220 of implanting the impurity GP into the insulating layer 120 using the plasma to be described later with reference to FIG. 6. As the impurities GP are implanted in the first plasma region PR1 and the second plasma region PR2 of the insulating layer 120, silicon atoms included in the insulating layer 120 may be detached from other atoms or may be replaced with the impurity GP. Thus, the number of holes or free electrons in the insulating layer 120 may increase.

A hole or a free electron formed in the first plasma region PR1 and the second plasma region PR2 of the insulating layer 120 may play a role in increasing carrier mobility, so that electrical conductivity of the first plasma region PR1 and electrical conductivity of the second plasma region PR2 are improved (e.g., are increased).

Because the number of the impurities GP implanted into the first plasma region PR1 is greater than the number of the impurities GP implanted in the second plasma region PR2, the number of holes or electrons formed in the first plasma region PR1 may be greater than the number of holes or electrons formed in the second plasma region PR2.

Accordingly, the electrical conductivity of the first plasma region PR1 may be higher (greater) than that of the second plasma region PR2, so that the electrical resistivity of the first plasma region PR1 is lower (less) than that of the second plasma region PR2.

In an embodiment, the first plasma region PR1 and the second plasma region PR2 may have different crystal structures. For example, the first plasma region PR1 of the insulating layer 120 may have an amorphous structure, and the second plasma region PR2 of the insulating layer 120 may have a crystalline structure. However, the crystal structures of the first plasma region PR1 and the second plasma region PR2 are not limited thereto, and may be variously changed.

For example, in the step S220 of implanting the impurity GP into the insulating layer 120 having the crystalline structure using the plasma to be described later with reference to FIG. 6, the crystal structure of the first plasma region PR1 of the insulating layer 120 may be changed, and the crystal structure of the second plasma region PR2 of the insulating layer 120 may be maintained without being changed. Thus, the crystal structures of the first plasma region PR1 and the second plasma region PR2 may become different.

This may be due to a difference between an energy according to an implanting angle of the impurities GP implanted into the first plasma region PR1 and an energy according to an implanting angle of the impurities GP implanted into the second plasma region PR2 in the step S220 of implanting the impurity GP into the insulating layer 120.

Specifically, as described above, the impurities GP implanted in the first plasma region PR1 of the insulating layer 120 with the crystalline structure may have relatively high (higher or greater) straightness compared with the impurities GP implanted in the second plasma region PR2 to have a high (a higher or greater) energy.

Accordingly, in a process of implanting plurality of the impurities GP with the high (the higher or greater) energy into first plasma region PR1, the crystal structure of the first plasma region PR1 may change.

On the other hand, the impurities GP implanted in the second plasma region PR2 of the insulating layer 120 with the crystalline structure may have relatively low (lower or less) straightness compared with the impurities GP implanted in the first plasma region PR1 to have a low (a lower or less) energy. The plurality of impurities GP implanted into the second plasma region PR2 may not have an (enough) energy required for (changing) the crystal structure of the second plasma region PR2, so that the crystal structure of the second plasma region PR2 may not be changed during a process of implanting the impurities GP into the second plasma region PR2.

A difference between the crystal structures of the first plasma region PR1 and the second plasma region PR2 may be due to a difference between the number of the impurities GP implanted in the first plasma region PR1 and the number of the impurities GP implanted in the second plasma region PR2, and/or a difference between implanting depths of the impurities GP implanted in the first plasma region PR1 and implanting depths of the impurities GP implanted in the second plasma region PR2.

Although FIG. 1 shows that the insulating layer 120 disposed on the substrate 100 includes one trench TRC, the present disclosure is not limited thereto, and the insulating layer 120 disposed on the substrate 100 may include a plurality of trenches TRC spaced apart from each other in the first direction X.

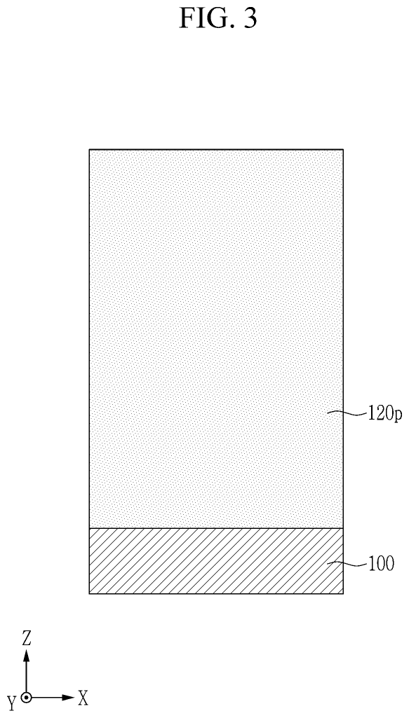

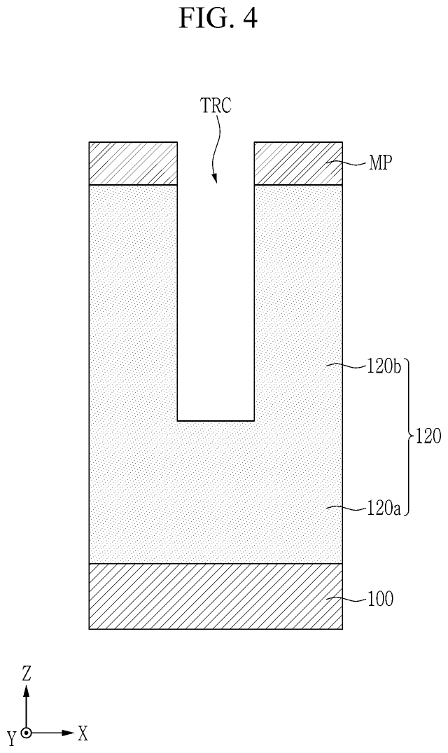

Hereinafter, a method for manufacturing the semiconductor device will be described with reference to FIGS. 3 to 14. Hereinafter, the same configurations described above may be referred to by the same reference numerals, and redundant description may be omitted or simplified, and a difference will be mainly described.

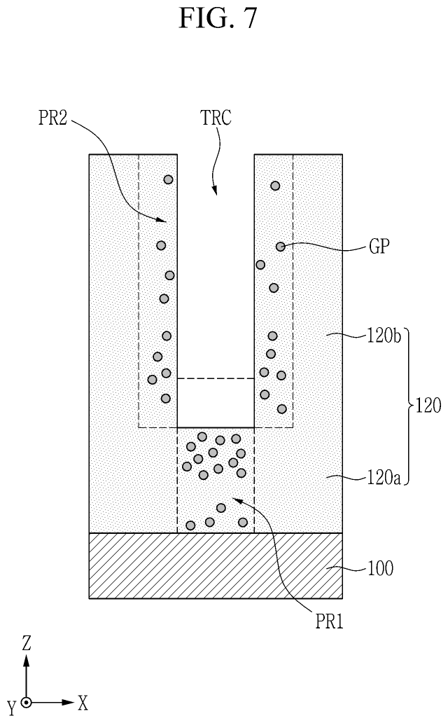

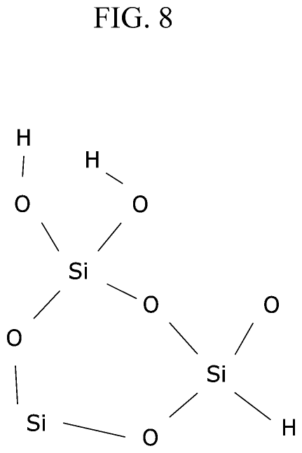

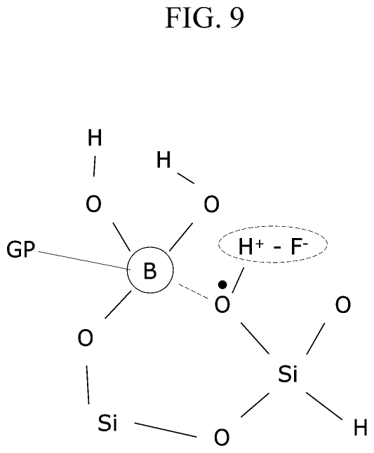

FIG. 3, FIG. 4, FIG. 6, and FIG. 7 are cross-sectional views for describing the method for manufacturing the semiconductor device according to some embodiments. FIG. 5 is a timing diagram showing a cycle of a process for etching a portion of the insulating layer (e.g., the insulating layer 120) according to some embodiments. FIG. 8 is a view showing a chemical structure before the impurity (e.g., the impurity GP) is implanted into the insulating layer (e.g., the insulating layer 120) including silicon oxide. FIG. 9 is a view showing a chemical structure after the impurity (e.g., the impurity GP) is implanted into the insulating layer (e.g., the insulating layer 120) including silicon oxide.

First, referring to FIG. 3, an insulating material layer 120p may be formed on the substrate 100. The substrate 100 may be, for example, a silicon wafer. In some embodiments, the substrate 100 may be the semiconductor substrate made of (including) the semiconductor material, or may be the semiconductor substrate with a semiconductor layer formed on a base substrate. The substrate 100 may include, for example, silicon, epitaxial silicon, germanium, silicon-germanium, silicon on insulator (SOI), germanium on insulator (GOI), or the like.

The insulating material layer 120p may be formed on an upper surface of the substrate 100. The insulating material layer 120p may include, for example, a silicon compound. For example, the insulating material layer 120p may include silicon oxide, silicon nitride, silicon oxynitride, a low-k material (a low dielectric constant material) such as SiOCN, SiOC, SiBN, SiBCN, and/or SiBCON, and/or a combination thereof. However, a material included in the insulating material layer 120p is an example and is not limited thereto, and may be variously changed.

Although FIG. 3 illustrates that the insulating material layer 120p is formed of a single layer, the insulating material layer 120p may be formed of (may include) multiple layers in which at least two layers are stacked. For example, the insulating material layer 120p may be formed of (may include) multiple layers in which a silicon oxide layer and a silicon nitride layer are alternately stacked.

Next, referring to FIG. 4 along with FIG. 3, a mask pattern MP that exposes at least a portion of the insulating material layer 120p may be formed on the insulating material layer 120p. The mask pattern MP may be patterned by a photolithography process. For example, the mask pattern MP may be a hard mask pattern, and the mask pattern MP may include, for example, silicon.

Next, the insulating layer 120 including the trench TRC may be formed by etching a portion of the insulating material layer 120p using the mask pattern MP as an etching mask. That is, by etching a portion of the insulating material layer 120p exposed by the mask pattern MP, the trench TRC recessed from an upper surface of the insulating material layer 120p toward a lower surface of the insulating material layer 120p may be formed. For example, a method of etching a portion of the insulating material layer 120p may be an anisotropic etching using plasma. However, the method of etching the insulating material layer 120p is not limited thereto, and may be variously changed.

As the portion of the insulating material layer 120p is etched, the first portion 120a of the insulating layer 120 extending in the first direction X that is a direction parallel to the substrate 100 and the second portions 120b of the insulating layer 120 extending from the first portion 120a in the third direction Z that is a direction perpendicular to the substrate 100 may be formed. The second portions 120b of the insulating layer 120 may be spaced apart from each other in the first direction X. An upper surface of the first portion 120a of the insulating layer 120 and (inner) side surfaces of the second portions 120b may define the trench TRC of the insulating layer 120.

Next, referring to FIGS. 5 to 7, in a process S200 of etching the lower surface of the trench TRC (e.g., the exposed portion of the upper surface of the first portion 120a of the insulating layer 120) of the insulating layer 120 according to an embodiment, a cycle in which a step (Depo) S210 of depositing a sacrificial pattern 130 using plasma, a step (Implant) S220 of implanting the impurity GP into the insulating layer 120 using plasma, and a step (Etch) S230 of etching a portion of the insulating layer 120 using plasma are sequentially performed may be repeated N times. The cycle of the process S200 of etching the lower surface of the trench TRC of the insulating layer 120 may be repeated N times until the trench TRC of the insulating layer 120 reaches a target depth.

In each cycle, each of the step (Depo) S210 of depositing the sacrificial pattern 130 using the plasma, the step (Implant) S220 of implanting the impurity GP into the insulating layer 120 using the plasma, and the step (Etch) S230 of etching the portion of the insulating layer 120 using the plasma may be performed at least once. The steps S210, S220, and S230 performed in each cycle may be successively (consecutively) performed. However, the present disclosure is not limited thereto, and in some embodiments, the steps S210, S220, and S230 performed in each cycle may be performed with time intervals.

Specifically, the step (Depo) S210 of depositing the sacrificial pattern 130 using the plasma may form the sacrificial pattern 130 on the insulating layer 120 and the mask pattern MP using the plasma. The sacrificial pattern 130 may be formed on an upper surface and a side surface of the mask pattern MP. That is, the sacrificial pattern 130 may be formed to cover (or overlap in the third direction Z) the upper surface of the mask pattern MP disposed on the upper surface of the insulating layer 120. As used herein, “an element A overlapping an element B in the first direction X” (or similar language) means that there is at least one line that extends in the first direction X and intersects both the elements A and B.

As shown in FIG. 6, the sacrificial pattern 130 may be formed on a side surface of the trench TRC formed in the insulating layer 120. That is, the sacrificial pattern 130 may be formed on the (inner) side surfaces of the second portions 120b of the insulating layer 120 constituting the side surface of the trench TRC. The sacrificial pattern 130 may not be formed on the upper surface of the first portion 120a of the insulating layer 120 that constitutes the lower surface of the trench TRC formed in the insulating layer 120.

A thickness of the sacrificial pattern 130 on a side surface of the mask pattern MP and the side surface of the trench TRC in the first direction X may decrease as the sacrificial pattern 130 approaches the substrate 100. For example, the closer the sacrificial pattern 130 to the substrate 100 is, the thinner the thickness of the sacrificial pattern 130 may be.

As the sacrificial pattern 130 is formed on the side surface of the trench TRC of the insulating layer 120, the lower surface of the trench TRC (at least a portion of the upper surface of the first portion 120a) may be exposed. Accordingly, in the step (Etch) S230 of etching the portion of the insulating layer 120 using the plasma that will be described later, a portion of the insulating layer 120 constituting the side surface of the trench TRC may be protected by the sacrificial pattern 130, and a portion of the insulating layer 120 constituting the lower surface of the trench TRC may be (further) exposed.

A first plasma gas used in the step (Depo) S210 of depositing the sacrificial pattern 130 may include at least two of carbon, hydrogen, and fluorine such as fluorinemethane (CH₃F), difluoromethane (CH₂F₂), fluoroform (CHF₃), carbon tetrafluoride (CF₄), difluoroacetylene (C₂F₂), tetrafluoroethylene (C₂F₄), hexafluoroethane (C₂F₆), hexafluoropropylene (C₃F₆), octafluoropropane (C₃F₈), tetrafluorobutatriene (C₄F₄), hexafluorobutadiene (C₄F₆), octafluorocyclobutane ₍c-C₄F₈), octafluorocyclopentane (C₅F₈), decafluorocyclopentane (C₅F₁₀), and/or the like. For example, the first plasma gas may include C₄F₆. C₄F₆ is an organic fluorine compound and has a relatively small (smaller) molecular weight. Thus, the sacrificial pattern 130 may be effectively formed by the first plasma gas that includes C₄F₆ on the side surface of the trench TRC (the inner side surfaces of the second portions 120b of the insulating layer 120) with a narrow width. However, the material included in the first plasma gas is not limited thereto, and may be variously changed.

In some embodiments, the first plasma gas used in the step (Depo) S210 of depositing the sacrificial pattern 130 may be a gas that further includes at least one of carbon (C) and hydrogen (H) in addition to boron (B). For example, the first plasma gas may include BH₃, B₂H, and/or B(CH₃)3.

Next, in the step (Implant) S220 of implanting the impurity GP into the insulating layer 120 using the plasma, the impurity GP included in the plasma gas may be implanted into the insulating layer 120.

Accordingly, the first plasma region PR1 into which the impurity GP is implanted may be formed at the first portion 120a of the insulating layer 120 disposed between the second portions 120b (in the first direction X) and constituting the lower surface of the trench TRC, and the second plasma region PR2 in which the impurity GP is implanted may be formed at the second portions 120b facing each other in the first direction X and constituting the side surface of the trench TRC.

In the step (Implant) S220 of implanting the impurity GP into the insulating layer 120 using the plasma, the impurities GP implanted into the first plasma region PR1 may be implanted at a narrow (a narrower) angle (angle range), and the impurities GP implanted into the second plasma region PR2 may be implanted at a relatively wide (wider) angle (angle range) compared with the impurities GP implanted in the first plasma region PR1. Here, the angle at which the impurities GP are implanted may refer to an angle with respect to the upper surface of the substrate 100.

Because the impurities GP implanted in the first plasma region PR1 have high (higher or greater) straightness, the impurities GP may be (more) easily implanted into the first plasma region PR1 compared with the impurities GP implanted into the second plasma region PR2. Accordingly, the number of the impurities GP implanted into the first plasma region PR1 may increase (may be greater than the number of the impurities GP implanted into the second plasma region PR2).

On the other hand, the impurities GP implanted into the second plasma region PR2 may have relatively low (lower or less) straightness compared with the impurities GP implanted into the first plasma region PR1, so that the number of the impurities GP implanted into the second plasma region PR2 may be less than the number of the impurities GP implanted into the first plasma region PR1. Accordingly, a concentration of the impurity GP included in the first plasma region PR1 may be greater than a concentration of the impurity GP included in the second plasma region PR2.

Because the impurities GP implanted into the first plasma region PR1 and the impurities GP implanted into the second plasma region PR2 have different implanting angles or straightnesses, a depth of the impurities GP implanted into the first plasma region PR1 and a depth of and the impurities GP implanted into the second plasma region PR2 may be different. The impurities GP implanted in the first plasma region PR1 may be implanted into a relatively deeper portion (may be implanted further into) compared with the impurities GP implanted in the second plasma region PR2. Here, a depth of the impurity GP implanted into the first plasma region PR1 may refer to a depth (a distance) of the impurity GP implanted in the third direction Z, and a depth of the impurity GP implanted into the second plasma region PR2 may refer to a depth (a distance) of the impurity GP implanted in the first direction X.

Accordingly, the depth of the first plasma region PR1 in the third direction Z may be different from the depth of the second plasma region PR2 in the first direction X. For example, because the impurities GP incident on the first plasma region PR1 are implanted deeper than the impurities GP incident on the second plasma region PR2, the depth of the first plasma region PR1 is the third direction Z may be greater than the depth of the second plasma region PR2 in the first direction X.

The impurities GP implanted in the first plasma region PR1 may have a concentration gradient in which a concentration of the impurities GP increases and then decreases from an upper region of the first plasma region PR1 to a lower region of the first plasma region PR1. The concentration of impurities GP implanted in the first plasma region PR1 may be the highest (greatest) at a central portion of the first plasma region PR1 (in the third direction Z).

This may be due to implanting angles or straightnesses of the impurities GP implanted into the first plasma region PR1. For example, the impurities GP that are implanted adjacent (closer) to the substrate 100 in the first plasma region PR1 are implanted with relatively small (smaller or narrower) implanting angles or high (higher or greater) straightnesses, and the impurities GP that are implanted adjacent (closer) to the lower surface of the trench TRC (the upper surface of the first portion 120a) in the first plasma region PR1 may be implanted with relatively large (larger or wider) implanting angles or low (lower or less) straightnesses.

As described above, the impurities GP implanted in the second plasma region PR2 may be implanted with a relatively large (larger or wider) implanting angle or low (lower or less) straightness compared with the impurities GP implanted in the first plasma region PR1, so that the impurities GP implanted into the second plasma region PR2 may be implanted to have a relatively wide (wider) distribution compared with the impurities GP implanted into the first plasma region PR1. Because the impurities GP implanted into the lower region of the second plasma region PR2 are implanted at a relatively narrow (narrower) angle compared with the impurities GP implanted into the upper region of the second plasma region PR2, the number of the impurities GP implanted into the lower region of the second plasma region PR2 may be greater than the number of the impurities GP implanted into the upper region of the second plasma region PR2.

Accordingly, a concentration of the impurity GP included in the lower region of the second plasma region PR2 may be higher than a concentration of the impurity GP included in the upper region.

In the step (Implant) S220 of implanting the impurity GP into the insulating layer 120 using the plasma, the impurity GP may be implanted into at least a portion of the sacrificial pattern 130 and at least a portion of the mask pattern MP.

A second plasma gas G2 used in the step (Implant) S220 of implanting the impurity GP into the insulating layer 120 using the plasma may be a gas including boron (B) or arsenic (As). For example, the second plasma gas G2 may include BH₃, B₂H, B(CH₃)₃, BF₃, BCl₂F, B₂F₄, B₃F₅, H₂BF, BOF, BOCl, BOBr, BF₃, and/or B₂H₆. As another example, the second plasma gas G2 may include AsH₅ and/or AsF₃.

In some embodiments, the second plasma gas G2 may include at least (any) two of boron (B), arsenic (As), and phosphorus (P). For example, second plasma gas G2 may include PH₃BH₃ and/or BCl₃PH₃. However, a material included in the second plasma gas G2 is not limited thereto, and may be variously changed.

Boron (B), arsenic (As), and phosphorus (P) included in the second plasma gas G2 may be the impurity GP implanted into the insulating layer 120.

If the second plasma gas G2 includes boron (B), an energy required for boron (B) to be implanted into the insulating layer 120 including silicon oxide or the like may be relatively low (lower or less) compared with an energy required for phosphorus (P). Thus, boron (B) may be more easily implanted inside the insulating layer 120 compared with phosphorus (P).

Because a covalent radius (or a covalent bond radius) of boron (B) has a smaller value compared with a covalent (bond) radius of phosphorus (P), boron (B) may have a relatively small (smaller) size compared with phosphorus (P). Accordingly, boron (B) may be (more) easily implanted inside the insulating layer 120 compared with phosphorus (P).

As the impurities GP are implanted into the first plasma region PR1 and the second plasma region PR2 in the step (Implant) S220 of implanting the impurity GP into the insulating layer 120 using the plasma, (physical and/or chemical) properties of the first plasma region PR1 and the second plasma region PR2 may be (may become) different.

For example, electrical resistivities and crystal structures of the first plasma region PR1 and the second plasma region PR2 may be different. As another example, a surface roughness (a degree of a surface roughness) of the first portion 120a of the insulating layer 120 where the first plasma region PR1 is disposed may be different from a surface roughness (a degree of a surface roughness) of the second portions 120b of the insulating layer 120 where the second plasma region PR2 is disposed.

Next, in the step (Etch) S230 of etching the portion of the insulating layer 120 using the plasma, a portion of the insulating layer 120 may be removed by (further) etching the lower surface of the trench TRC (the exposed upper surface of the first portion 120a) of the insulating layer 120 into which the impurities GP are implanted.

Specifically, as shown in FIG. 6 and FIG. 7, the lower surface of the trench TRC (the upper surface of the first portion 120a or the upper surface of the first plasma region PR1) exposed by the sacrificial pattern 130 may be (further) etched toward the substrate 100. That is, a portion of the first portion 120a that constitutes the lower surface of the trench TRC and is disposed between the second portions 120b of the insulating layer 120 (in the first direction X) may be etched (further recessed) in the third direction Z. As described above, the first portion 120a that constitutes the lower surface of the trench TRC and is disposed between the second portions 120b of the insulating layer 120 (in the first direction X), may be (may include) the first plasma region PR1 into which the impurities GP are implanted.

A third plasma gas used in the step (Etch) S230 of etching the portion of the insulating layer 120 using the plasma may include an interhalogen compound, fluorine, and/or hydrogen. For example, the third plasma gas may include H₂, CF₄, C₄F₆, C₄F₈, CHF₃, SF₆, NF₃, XeF₂, TaF₅, IF₇, HF, ClF₃, BrF₃, AsF₅, PF₅, NbF₅, BiF₅, UF5, SiCl4, TaCl5, and/or HfCI4. However, a material included in the third plasma gas is not limited thereto, and may be variously changed.

In some embodiments, the third plasma gas may be halide including fluorine (F) or a boron (B) gas including oxyhalide. For example, the third plasma gas may include BF₃, BCl₂F, B₂F₄, B₃F₅, H₂BF, BOF, BOCl, and/or BOBr.

As described above, because the impurities GP are implanted into the first plasma region PR1 (that is, a portion of the first portion 120a that constitutes the lower surface of the trench TRC and is disposed between the second portions 120b of the insulating layer 120 in the first direction X), etching of the first plasma region PR1 may be smoothly performed. Because the impurity GP is implanted into the first portion 120a of the insulating layer 120 including the first plasma region PR1, physical and/or chemical properties of the first portion 120a of the insulating layer 120 including the first plasma region PR1 may change so that difficulty of the etching process may be reduced. Because the impurity GP is implanted into the first portion 120a of the insulating layer 120 including the first plasma region PR1, a coupling structure of the first plasma region PR1 may be changed to facilitate etching, or reactivity with the third plasma gas used for etching may be improved (e.g., increased). For example, the first plasma region PR1 may be more easily etched by the third plasma gas than other regions of the insulating layer 120, which are not implanted by the impurity GP.

For example, as shown in FIG. 8 and FIG. 9, if the impurity GP is implanted into the insulating layer 120 including silicon oxide using the second plasma gas G2 including the impurity GP (for example, boron (B)), the impurity GP may break a bond between silicon (Si) and oxygen (O) and may combine with three oxygens (O) to form a BO₃ compound. Accordingly, oxygen (O) that does not combine with the impurity GP may occur (may be generated).

Next, if a portion of the insulating layer 120 into which the impurity GP is implanted is etched using the third plasma gas (e.g., HF), reactivity to the third plasma gas (e.g., HF) of the insulating layer 120 that is a subject of etching may be improved (e.g., increased) by electrostatic attraction between hydrogen (H) of HF in a dipole state and oxygen (O) that does not combine with another element (silicon (Si) or the impurity GP (e.g., boron (B))).

An adsorption energy with the third plasma gas (e.g., an adsorption energy between the impurity GP and HF) in a case where the impurity GP is implanted within the insulating layer 120, including silicon oxide, may be relatively large (larger or greater) compared to a case where the impurity GP is not implanted within the insulating layer 120 including silicon oxide.

Because the adsorption energy with the third plasma gas (e.g., HF) increases, combination of the insulating layer 120 and the third plasma gas (e.g., HF) may become easy (easier or stronger). Thus, an etching process for the insulating layer 120, including silicon oxide, into which the impurity GP is implanted may be (more) smoothly (easily) performed compared with an etching process for the insulating layer 120, including silicon oxide, into which the impurity GP is not implanted.

FIGS. 8 and 9 illustrate that the insulating layer 120 includes silicon oxide and that the impurity GP is boron (B), but the present disclosure is not limited thereto. For example, even if the impurity GP includes phosphorus (P) or arsenic (As), the contents (the mechanism) thereof may be substantially the same as the mechanism of the embodiments in FIGS. 8 and 9. That is, if the impurity GP (for example, phosphorus (P) or arsenic (As)) is implanted into the insulating layer 120, including silicon oxide, the impurity GP may break a bond between silicon (Si) and oxygen (O), and may combine with four oxygens (O) to form a compound.

Here, if the impurity GP that is a Group 15 element combines with four oxygens (O), the impurity GP may take on a negative charge due to the remaining electron with which is not combined. Thus, reactivity between the insulating layer 120 that is a subject of etching and the third plasma gas including, for example, HF may be improved (increased) by electrostatic attraction between hydrogen (H) of HF in a dipole state and the impurity GP taking on the negative charge.

In a process of etching the lower surface of the trench TRC (the upper surface of the first portion 120a of the insulating layer 120 or the upper surface of the first plasma region PR1) formed in the insulating layer 120 using plasma, (at least a portion of) the sacrificial pattern 130 may be removed together. The remaining sacrificial pattern 130 that is not removed during an etching process of the lower surface of the trench TRC may be removed through an additional cleaning process.

Next, mask patterns MP formed on upper surfaces of the second portions 120b of the insulating layer 120 may be removed.

In some embodiments, at least one of the first plasma gas and the third plasma gas used in each of the step (Depo) S210 of depositing the sacrificial pattern 130 using the plasma and the step (Etch) S230 of etching the portion of the insulating layer 120 using the plasma included in the process S200 of etching the lower surface of the trench TRC of the insulating layer 120, may include boron (B).

For example, any one of the first plasma gas and the third plasma gas may include boron (B). As another example, the first plasma gas and third plasma gas may include boron (B).

According to the method for manufacturing the semiconductor device according to the embodiment, in the process S200 of etching the lower surface of the trench TRC of the insulating layer 120, the step (Implant) S220 of implanting the impurity GP into the insulating layer 120 using the plasma may be performed between the step (Depo) S210 of depositing the sacrificial pattern 130 using the plasma and the step (Etch) S230 of etching the portion of the insulating layer 120 using the plasma. Thus, even if a width of the trench TRC formed in the insulating layer 120 is narrow and an aspect ratio of the trench TRC is large, etching on the lower surface of the trench TRC may be smoothly (easily) performed. Because the step (Implant) S220 of implanting the impurity GP on the lower surface of the trench TRC is performed, the semiconductor device with improved productivity and reliability may be provided by easily adjusting an etching level while lowering difficulty of the etching process by changing physical and/or chemical properties of the lower surface of the trench TRC (the upper surface of the first portion 120a of the insulating layer 120 or the upper surface of the first plasma region PR1).

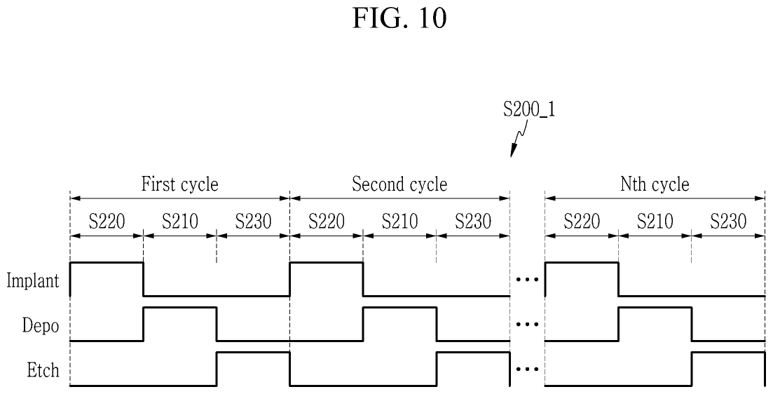

Hereinafter, the method for manufacturing the semiconductor device according to some embodiments will be described with reference to FIGS. 10 to 14. Hereinafter, the same configurations described above may be referred to by the same reference numerals, and redundant description may be omitted or simplified, and a difference will be mainly described.

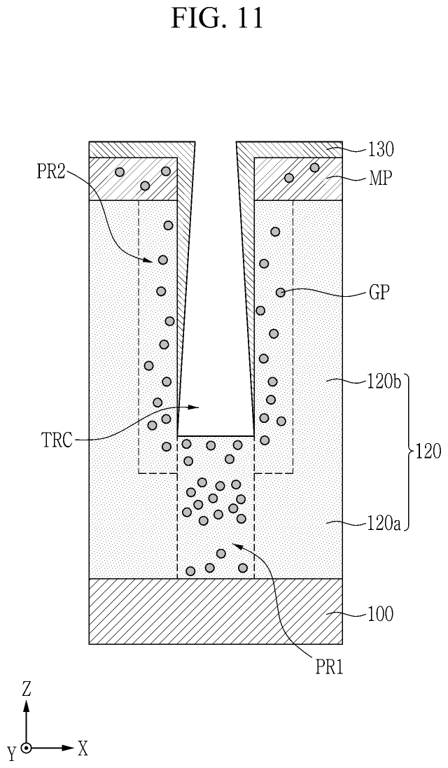

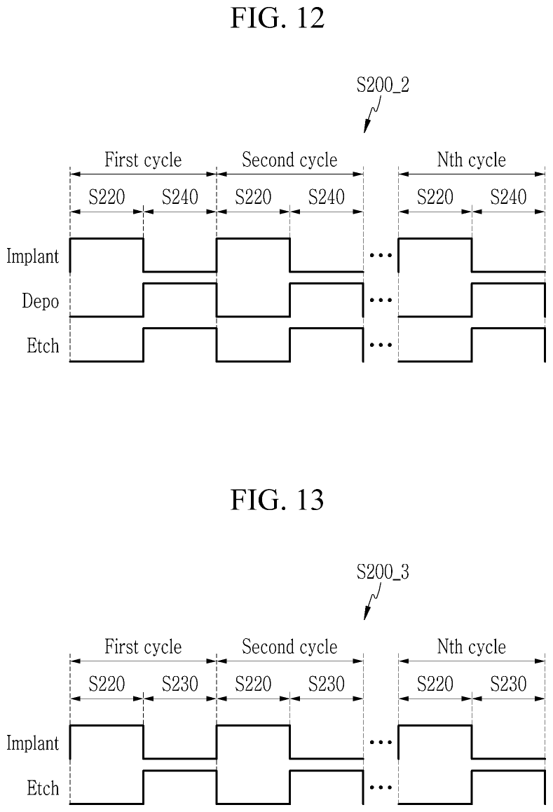

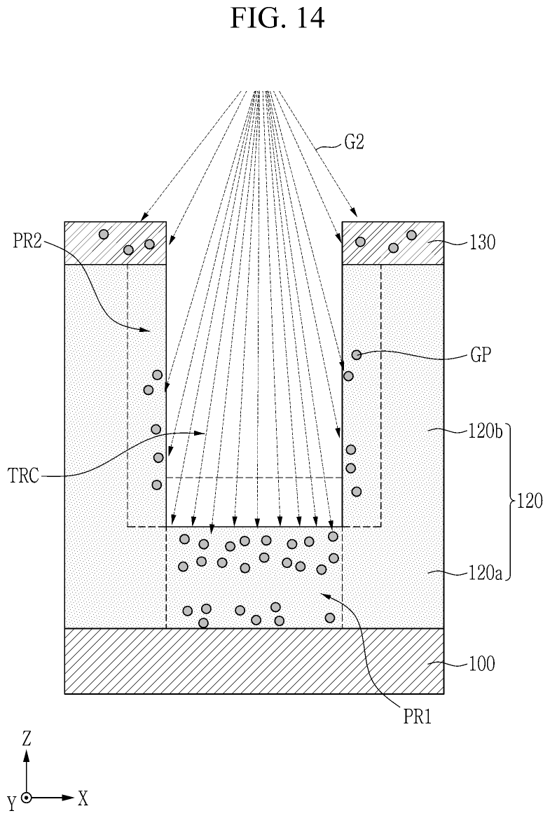

FIG. 10, FIG. 12, and FIG. 13 are timing diagrams showing a cycle of a process of etching a portion of the insulating layer (e.g., the insulating layer 120) according to some embodiments. FIG. 11 and FIG. 14 are cross-sectional views for describing a method for manufacturing the semiconductor device according to some embodiments.

According to the embodiment shown in FIG. 10 and FIG. 11, unlike the embodiment shown in FIG. 5, an order of a process S200_1 of etching the lower surface of the trench TRC (the upper surface of the first portion 120a of the insulating layer 120 or the upper surface of the first plasma region PR1) of the insulating layer 120 may be different from the process S200 shown in FIG. 5. For example, as shown in FIG. 10, in the process S200_1 of etching the lower surface of the trench TRC of the insulating layer 120 according to the present embodiment, a cycle in which the step (Implant) S220 of implanting the impurity GP into the insulating layer 120 using the plasma, the step (Depo) S210 of depositing the sacrificial pattern 130 using the plasma, and the step (Etch) S230 of etching the portion of the insulating layer 120 using the plasma are sequentially performed, may be repeated N times. That is, unlike the embodiment (e.g., the process S200) shown in FIG. 5, in the process S200_1 of etching the lower surface of the trench TRC of the insulating layer 120 according to the present embodiment, the step (Implant) S220 of implanting the impurity GP into the insulating layer 120 using the plasma may be performed before the step (Depo) S210 of depositing the sacrificial pattern 130 using the plasma in one (in the same) cycle.

According to the embodiments shown in FIG. 10 and FIG. 11, the step (Implant) S220 of implanting the impurity GP may be performed before the sacrificial pattern 130 is formed on the mask pattern MP and the insulating layer 120 in one (in the same) cycle, so that the impurities GP may not be implanted into the sacrificial pattern 130.

The number of the impurities GP implanted into the second plasma region PR2 and the mask pattern MP of the embodiment shown in FIG. 11 may be greater than that of the embodiment shown in FIG. 6. That is, the mask pattern MP and the second plasma region PR2 may be directly exposed to the second plasma gas G2 in a process of implanting the impurity GP into the insulating layer 120 using the second plasma gas G2 before the sacrificial pattern 130 is formed, so that the impurity GP may be more easily implanted. Thus, the number of the impurities GP implanted into the second plasma region PR2 and the mask pattern MP of the embodiment shown in FIG. 11 may be relatively greater than that of the embodiment shown in FIG. 6.

Next, the step (Etch) S230 of etching the portion of the insulating layer 120 using the plasma may be performed. A description of the step (Etch) S230 of etching the portion of the insulating layer 120 using the plasma is substantially the same as the step (Etch) S230 of etching the portion of the insulating layer 120 using the plasma described with reference to FIG. 5, so that the description thereof is omitted.

Unlike the embodiment shown in FIG. 11, in a process S200_2 of etching the lower surface of the trench TRC of the insulating layer 120 according to the embodiment shown in FIG. 12, a cycle, in which the step (Implant) S220 of implanting the impurity GP into the insulating layer 120 using the plasma and a step S240 of depositing (Depo) the sacrificial pattern 130 using the plasma and simultaneously etching (Etch) the portion of the insulating layer 120 using the plasma are sequentially performed, may be repeated N times. That is, unlike the embodiment shown in FIG. 11, in the process S200_2 of etching the lower surface of the trench TRC according to the present embodiment in FIG. 12, the step (Depo) S210 of FIG. 11 of depositing the sacrificial pattern 130 using the plasma and the step (Etch) S230 of FIG. 11 of etching the portion of the insulating layer 120 using the plasma may be simultaneously performed.

A gas used in the step S240 of depositing (Depo) the sacrificial pattern 130 using the plasma and simultaneously etching (Etch) the portion of the insulating layer 120 using the plasma according to the present embodiment in FIG. 12 may be a gas obtained by mixing the first plasma gas used in the step (Depo) S210 of depositing the sacrificial pattern 130 with the third plasma gas used in the step (Etch) S230 of etching the portion of the insulating layer 120.

Unlike the embodiment shown in FIG. 5, the step (Depo) S210 of depositing the sacrificial pattern 130 using the plasma may be omitted in a process S200_3 of etching the lower surface of the trench TRC of the insulating layer 120 according to the embodiment shown in FIG. 13 and FIG. 14. In the process S200_3 of etching the lower surface of the trench TRC of the insulating layer 120 according to the present embodiment in FIGS. 13 and 14, a cycle, in which the step (Implant) S220 of implanting the impurity GP into the insulating layer 120 using the plasma (e.g., the second plasma gas G2) and the step (Etch) S230 of etching the portion of the insulating layer 120 are sequentially performed, may be repeated N times.

As shown in FIG. 14, a width in the first direction X of the trench TRC formed in the insulating layer 120 according to the present embodiment may be greater than that of the trench TRC formed in the insulating layer 120 according to the embodiment of FIG. 6. That is, a distance between the second portions 120b of the insulating layer 120 constituting the side surfaces of the trench TRC according to the present embodiment may be greater than a distance between the second portions 120b of the insulating layer 120 constituting the side surfaces of the trench TRC according to the embodiment shown in FIG. 6.

Accordingly, even if the sacrificial pattern 130 of FIG. 6 is not formed on the side surfaces of the trench TRC by performing the step (Depo) S210 of FIG. 5 of depositing the sacrificial pattern 130 using the plasma, the side surfaces of the trench TRC may not be etched together in the step (Etch) S230 of etching the portion of the insulating layer 120.

Also, as shown in FIG. 14, the number of the impurities GP implanted in the second plasma region PR2 formed in the second portions 120b of the insulating layer 120 constituting the side surface of the trench TRC may be smaller than the number of the impurities GP implanted into the second plasma region PR2 according to the embodiment shown in FIG. 6.

As described above, because a width of the trench TRC according to the present embodiment in the first direction X is greater than a width of the trench TRC according to the embodiment in shown in FIG. 6 in the first direction X, implanting angles of the impurities GP implanted into the second plasma region PR2 may increase and straightnesses of the impurities GP implanted into the second plasma region PR2 may decrease. Thus, it may not be easy (may be harder) to implant the impurity GP into the second plasma region PR2.

Because a small number of the impurities GP are implanted into the second plasma region PR2 compared with the first plasma region PR1, as described above, reactivity to the plasma gas used in the step (Etch) S230 of etching the portion of the insulating layer 120 may be low (lower). That is, even if the second plasma region PR2 formed in the second portions 120b of the insulating layer 120 constituting the side surface of the trench TRC is exposed to the plasma gas for etching, the reactivity to the plasma gas for etching may be low (lower). Thus, the side surface of the trench TRC may not be (easily) etched.

On the other hand, because the first plasma region PR1 formed in the first portion 120a of the insulating layer 120 constituting the lower surface of the trench TRC has a larger number of the implanted impurities GP than the second plasma region PR2, reactivity to the plasma gas used in the step (Etch) S230 of etching the portion of the insulating layer 120 may be higher.

The impurity GP may be implanted into the mask pattern MP in the step (Implant) S220 of implanting the impurity GP into the insulating layer 120 according to the present embodiment, so that a film quality (e.g., the physical strength or hardness) of the mask pattern MP may be strengthened. For example, as described above, the second plasma gas G2 used in the step (Implant) S220 of implanting the impurity GP into the insulating layer 120 may include boron (B). If the mask pattern MP for patterning is a silicon mask and boron (B) is implanted into the mask pattern MP, the film quality (e.g., the physical strength or hardness) of the mask pattern MP may be strengthened. Accordingly, in the step (Etch) S230 of etching the portion of the insulating layer 120, the mask pattern MP may prevent the upper surfaces of the second portions 120b of the insulating layer 120 disposed below the mask pattern MP from being etched together.

The embodiments of FIGS. 10 to 14 may have substantially the same effect as that of the embodiments of FIGS. 5 to 7.

While this disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

What is claimed is:

1. A method for manufacturing a semiconductor device, comprising:
forming an insulating layer including a silicon compound on a substrate;
forming a trench by recessing a portion of the insulating layer toward the substrate, wherein the trench is adjacent a first portion of the insulating layer and a second portion of the insulating layer;
implanting a first impurity with a first concentration in the first portion of the insulating layer;
implanting a second impurity with a second concentration in the second portion of the insulating layer, wherein the implanting the first impurity and the implanting the second impurity are performed simultaneously; and
etching the first portion of the insulating layer after the implanting the first impurity,
wherein the first impurity and the second impurity each include at least one of boron and arsenic.

2. The method of claim 1, wherein the first concentration is greater than the second concentration.

3. The method of claim 1, wherein an upper surface of the first portion of the insulating layer is rougher than a side surface of the second portion of the insulating layer.

4. The method of claim 1, wherein an electrical resistivity of the first portion of the insulating layer is less than an electrical resistivity of the second portion of the insulating layer.

5. The method of claim 1, wherein the first portion of the insulating layer includes an amorphous structure, and the second portion of the insulating layer includes a crystalline structure.

6. The method of claim 1, wherein each of the first impurity and the second impurity further includes phosphorus.

7. A method for manufacturing a semiconductor device, comprising:
forming an insulating layer including a silicon compound on a substrate;
forming a mask pattern on the insulating layer;
forming a trench in the insulating layer by patterning the insulating layer through the mask pattern, wherein an upper surface of a first portion of the insulating layer and an inner side surface of a second portion of the insulating layer are exposed to the trench;
implanting a first impurity into the first portion of the insulating layer by using a first plasma gas; and
etching the first portion of the insulating layer by using a second plasma gas,
wherein the first impurity includes at least one of boron and arsenic.

8. The method of claim 7, further comprising:
forming a sacrificial layer on the mask pattern and the inner side surface of the second portion of the insulating layer by using a third plasma gas.

9. The method of claim 8, wherein the forming the sacrificial layer is performed after the implanting the first impurity.

10. The method of claim 9, wherein the forming the sacrificial layer is performed simultaneously with the etching the first portion of the insulating layer.

11. The method of claim 8, wherein the implanting the first impurity is performed after the forming the sacrificial layer.

12. The method of claim 11, wherein the etching the first portion of the insulating layer is performed after the implanting the first impurity.

13. The method of claim 12, wherein a unit cycle, including the forming the sacrificial layer, the implanting the first impurity, and the etching the first portion of the insulating layer, is repeated more than once.

14. The method of claim 12, wherein the first plasma gas, the second plasma gas, and the third plasma gas each include boron.

15. The method of claim 7, wherein the first plasma gas includes boron, the mask pattern includes silicon, and the boron is implanted into the mask pattern during the implanting the first impurity.

16. The method of claim 7, wherein the first plasma gas includes at least two of boron, arsenic, and phosphorus.

17. The method of claim 7, wherein during the implanting the first impurity, a second impurity is implanted into the second portion of the insulating layer, and
wherein the second impurity includes at least one of boron and arsenic.

18. The method of claim 17, wherein a first concentration of the first impurity in the first portion of the insulating layer is greater than a second concentration of the second impurity in the second portion of the insulating layer.

19. A method for manufacturing a semiconductor device, comprising:
forming an insulating layer that includes a silicon compound on a substrate;
forming a mask pattern on the insulating layer;
forming a trench in the insulating layer by patterning the insulating layer through the mask pattern;
forming a sacrificial layer on the mask pattern and an inner side surface of the insulating layer, which is exposed to the trench, by using a first plasma gas;
implanting an impurity into an upper surface of the insulating layer, which is exposed to the trench, by using a second plasma gas; and
etching the upper surface of the insulating layer by using a third plasma gas,
wherein a unit cycle, in which the forming the sacrificial layer, the implanting the impurity, and the etching the upper surface of the insulating layer is sequentially performed, is repeated more than once, and
wherein the first plasma gas, the second plasma gas, and the third plasma gas include boron.

20. The method of claim 19, wherein the first plasma gas further includes at least one of carbon and hydrogen, and
wherein the second plasma gas includes at least two of boron, arsenic, and phosphorus.
